(19) United States
(12) Patent Application Publication
(10) Pub. No.: US 2022/0190281 A1
(43) Pub. Date: Jun. 16, 2022

(54) ORGANIC LIGHT EMITTING DIODE DISPLAY PANEL

(71) Applicant: Shenzhen China Star Optoelectronics Semiconductor Display Technology Co., Ltd., Shenzhen (CN)

(72) Inventors: Shuning ZHAO, Shenzhen (CN); Yuanjun HSU, Shenzhen (CN)

(21) Appl. No.: 16/615,834

(22) PCT Filed: Oct. 15, 2019
(86) PCT No.: PCT/CN2019/111260

§ 371 Date: Nov. 22, 2019

(30) Foreign Application Priority Data
Aug. 9, 2019 (CN) 201910734007.9

(51) Int. Cl. H01L 51/52; H01L 27/32

(52) U.S. Cl. CPC H01L 51/5228; H01L 27/3279; H01L 27/322; H01L 2251/308; H01L 2251/558

(57) ABSTRACT

An organic light emitting diode display panel, including, a first substrate; a thin film transistor layer disposed on the first substrate; a light emitting device layer disposed on the thin film transistor layer; a second substrate disposed opposite to the first substrate; a color filter layer disposed on the second substrate; a protective layer disposed on the color filter layer; a plurality of cathode auxiliary wires disposed on the protective layer in a crisscross manner; wherein the cathode auxiliary wire and the cathode layer are electrically connected to reduce an IR drop of the cathode layer.

### FIELD OF INVENTION

The present invention relates to the field of display technology, and in particular, to an organic light emitting diode display panel.

### BACKGROUND OF INVENTION

At present, a cathode of an organic light emitting diode light emitting device is a full surface metal. In order to increase transmittance of light, the cathode layer needs to be made as thin as possible. However, the thinner the cathode layer, the larger the resistance. When energizing the cathode layer from an edge of a display panel, a voltage drop (IR drop) will gradually increase from the edge of the display panel to the middle thereof.

After the display panel is lit, a phenomenon that the edge of the display panel is bright but the middle thereof is dark will occur.

### Technical Problem

As shown in FIG. 1, it is a conventional organic light emitting diode display panel 10, including, a first substrate 100, a thin film transistor layer 101, an anode layer 102, a pixel defining layer 103, an organic light emitting layer 104, and a cathode layer 105. In order to increase transmittance of light, the cathode layer 105 needs to be made as thin as possible. However, the thinner the cathode layer 105, the larger the resistance. When energizing the cathode layer 105 from an edge of a display panel, a voltage drop (IR drop) will gradually increase from the edge to middle of the display panel. After the display panel is lit, a phenomenon that an edge of the display panel is bright but the middle thereof is dark will occur.

### SUMMARY OF INVENTION

In order to solve the above problem, the present invention provides an organic light emitting diode (OLED) display panel, which can reduce IR drop of the OLED display panel, and improve the problem that an edge of the display panel is bright but the middle thereof is dark. The invention adds cathode auxiliary wires on a side of the color filter substrate, and contacts the cathode auxiliary wires with the cathode layer of the OLED display panel after the display panel is bonded. Since IR drop of the cathode auxiliary wire is small, the IR drop of the display panel can be reduced after the cathode auxiliary wires contact with the cathode layer of the OLED display panel.

In order to achieve the above object, the present invention provides an OLED display panel, including: a first substrate; a thin film transistor layer disposed on the first substrate; a light emitting device layer disposed on the thin film transistor layer, including: an anode layer, a pixel defining layer, an organic light emitting layer, and a cathode layer; a second substrate disposed opposite to the first substrate; a color filter layer disposed on the second substrate, including a plurality of sub-pixels arranged in an array and a crisscrossed black matrix, wherein each of the sub-pixels is separated by the black matrix; a protective layer disposed on the color filter layer; a plurality of cathode auxiliary wires disposed on the protective layer in a crisscross manner; wherein the cathode auxiliary wire and the cathode layer are electrically connected to reduce a voltage drop (IR drop) of the cathode layer.

Preferably, the cathode auxiliary wires correspond to a pattern of the black matrix, and are disposed on the protective layer in a crisscross manner.

Preferably, the cathode auxiliary wire is composed of any one of indium tin oxide, indium doped zinc oxide, silver magnesium, and an indium tin oxide/silver/indium tin oxide composite.

Preferably, the cathode auxiliary wire has a thickness of 300-5000 Å.

Preferably, the anode layer is composed of any one of indium tin oxide, indium doped zinc oxide, and an indium tin oxide/silver/indium tin oxide composite.

Preferably, the anode layer has a thickness of 100-3000 Å.

Preferably, the color filter layer has a thickness of 5000-50000 Å.

Preferably, the cathode layer is composed of any one of silver magnesium, indium doped zinc oxide, indium tin oxide, aluminum, indium tin oxide/silver/indium tin oxide composite, and indium doped zinc oxide/silver/indium doped zinc oxide composite.

Preferably, the cathode layer has a thickness of 100-3000 Å.

Preferably, the protective layer has a thickness of 5000-50000 Å.

The present invention further provides another organic light emitting diode display panel, including: a first substrate; a thin film transistor layer disposed on the first substrate; a light emitting device layer disposed on the thin film transistor layer, including: an anode layer, a pixel defining layer, an organic light emitting layer, and a cathode layer; a second substrate disposed opposite to the first substrate; a color filter layer disposed on the second substrate, including a plurality of sub-pixels arranged in an array and a crisscrossed black matrix, wherein each of the sub-pixels is separated by the black matrix; a protective layer disposed on the color filter layer; a plurality of cathode auxiliary wires, the cathode auxiliary wire each is composed of any one of indium tin oxide, indium doped zinc oxide, silver magnesium, and an indium tin oxide/silver/indium tin oxide composite; wherein the cathode auxiliary wires correspond to a pattern of the black matrix, and are disposed on the protective layer in a crisscross manner; and wherein the cathode auxiliary wire and the cathode layer are electrically connected to reduce a voltage drop (IR drop) of the cathode layer.

Preferably, the cathode auxiliary wire has a thickness of 300-5000 Å.

Preferably, the anode layer is composed of any one of indium tin oxide, indium doped zinc oxide, and an indium tin oxide/silver/indium tin oxide composite.

Preferably, the anode layer has a thickness of 100-3000 Å.

Preferably, the color filter layer has a thickness of 5000-50000 Å.

Preferably, the cathode layer is composed of any one of silver magnesium, indium doped zinc oxide, indium tin oxide, aluminum, indium tin oxide/silver/indium tin oxide composite.

Preferably, the cathode layer has a thickness of 100-3000 Å.

Preferably, the protective layer has a thickness of 5000-50000 Å.

### Beneficial Effect

An organic light emitting diode (OLED) display panel provided by the present invention can reduce IR drop of the OLED display panel by the electrical connection between the cathode auxiliary wire 213 and the cathode layer 205, consequently solving the problem that an edge of the OLED display panel is bright but the middle thereof is dark.

### DESCRIPTION OF DRAWINGS

In order to more clearly illustrate the technical solutions in the embodiments of the present invention, the following figures described in the embodiments will be briefly introduced. It is obvious that the drawings described below are merely some embodiments of the present invention, other drawings can also be obtained by the person ordinary skilled in the field based on these drawings without doing any creative activity.

FIG. 1 is a conventional organic light emitting diode display panel.

FIG. 2 is an organic light emitting diode display panel according to an embodiment of the present invention.

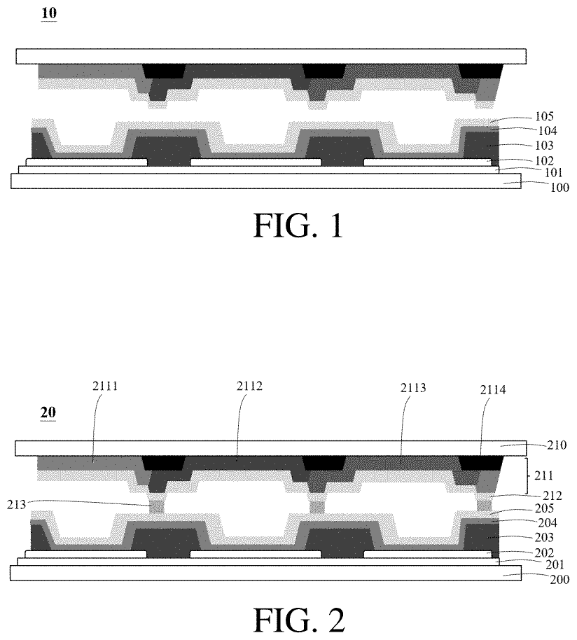

### DETAILED DESCRIPTION OF PREFERRED EMBODIMENTS

The technical solutions in the embodiments of the present invention will be clearly and completely described in the following with reference to the accompanying drawings. It is obvious that the drawings described below are merely some embodiments of the present invention, all other embodiments obtained by a person ordinarily skilled in the art based on the embodiments without doing any creative activity are within the scope of the present application.

The following description of the various embodiments is provided to illustrate the specific embodiments of the invention. The directional terms mentioned in the present invention, such as “on,” “below”, “front”, “behind”, “left”, “right”, “inside”, “outside”, “side”, etc., are merely references of the direction in the drawings. Therefore, the directional terminology used is for the purpose of illustration and understanding of the invention rather than limiting the invention.

As shown in FIG. 2, the organic light emitting diode (OLED) display panel 20 of an embodiment of the present invention includes: a first substrate 200; a thin film transistor layer 201 disposed on the first substrate 200; a light emitting device layer disposed on the thin film transistor layer 201, including an anode layer 202, a pixel defining layer 203, an organic light emitting layer 204, and a cathode layer 205; a second substrate 210 disposed opposite to the first substrate 200; a color filter layer 211 having a thickness of 5000-50000 Å disposed on the second substrate 210, including a plurality of red sub-pixels 211, green sub-pixels 2112, blue sub-pixels 2113 arranged in an array, and a black matrix 2114, each sub-pixel is separated by the black matrix 2114; a protective layer 212 having a thickness of 5000-50000 Å disposed on the color filter layer 211; a plurality of cathode auxiliary wires 213 disposed on the protective layer 212 in a crisscross manner; wherein the cathode auxiliary wire 213 and the cathode layer 205 are electrically connected to reduce IR drop of the cathode layer.

The cathode auxiliary wire 213 corresponds to a pattern of the black matrix 2114, disposed on the protective layer 212 in a crisscross manner, and is electrically connected to the cathode layer 205.

The cathode auxiliary wire 213 is composed of any one of indium tin oxide, indium doped zinc oxide, silver magnesium (MgAg), and an indium tin oxide/silver/indium tin oxide composite. The cathode auxiliary wire 213 has a thickness of 300-5000 Å.

The anode layer 202 is composed of any one of indium tin oxide, indium doped zinc oxide, and an indium tin oxide/silver/indium tin oxide composite. The anode layer 202 has a thickness of 100-3000 Å.

The cathode layer 205 is composed of any one of silver magnesium, indium doped zinc oxide, indium tin oxide, aluminum, indium tin oxide/silver/indium tin oxide composite, and indium doped zinc oxide/silver/indium doped zinc oxide composite. The cathode layer 205 has a thickness of 100 to 3000 Å.

The preparing process of the OLED display panel 20 of the embodiment of the present invention includes:

After cleaning the second substrate 210, forming a color filter layer 211 thereon, coating a black matrix layer material on the second substrate 210, and defining a pattern of the black matrix 2114 by processes of exposure, development, and the like.

Next, coating a layer of red sub-pixel photoresist, defining a pattern of the red sub-pixel 2111 by exposure, development, and the like.

Following, coating a layer of green sub-pixel photoresist, defining a pattern of the green sub-pixel 2112 by exposure, development, and the like.

Next, coating a layer of blue sub-pixel photoresist, defining a pattern of the blue sub-pixel 2113 by exposure, development, and the like.

Following, coating a protective layer material on the color filter layer 211 to form a protective layer 212 for covering the color filter layer 211.

Finally, forming a cathode auxiliary wire layer on the protective layer 212 by depositing, defining a pattern of the cathode auxiliary wire 213 by photoresist coating, exposure, development, etching, etc., to complete preparation of the color filter substrate.

Following, forming a metal layer on the other first substrate 200 by depositing, and forming a pattern of thin-film transistor layer 201 by photoresist coating, exposure, development, etching, and the like.

Next, forming an anode layer metal on the thin film transistor layer 201 by depositing, and defining a pattern of the anode layer 202 by photoresist coating, exposure, development, etching, and the like.

Following, coating an organic photoresist on the anode layer 202, and completing the pixel definition layer 203 by processes of exposure and development, etc.

Following, evaporating an organic light emitting material on the pixel defining layer 203 to form the organic light emitting layer 204.

Next, forming a cathode layer 205 on an organic light emitting layer 204 by depositing and the preparation of the array substrate is completed.

After finishing the above processes, the second substrate and the first substrate are bonded together to complete the preparation of the OLED display panel 20.

An OLED display panel of the present invention can reduce IR drop of the OLED display panel by an electrical connection between the cathode auxiliary wire 213 and the cathode layer 205, thereby solving the problem that an edge of the OLED display panel is bright but the middle thereof is dark.

The description of the above exemplary embodiments is only for the purpose of understanding the invention. It is to be understood that the present invention is not limited to the disclosed exemplary embodiments. It is obvious to those skilled in the art that the above exemplary embodiments may be modified without departing from the scope and spirit of the present invention.

What is claimed is:

1. An organic light emitting diode (OLED) display panel, comprising:
a first substrate;
a thin film transistor layer disposed on the first substrate;
a light emitting device layer disposed on the thin film transistor layer, comprising: an anode layer, a pixel defining layer, an organic light emitting layer, and a cathode layer;
a second substrate disposed opposite to the first substrate;
a color filter layer disposed on the second substrate, comprising a plurality of sub-pixels arranged in an array and a crisscrossed black matrix, wherein each of the sub-pixels is separated by the black matrix;
a protective layer disposed on the color filter layer;
a plurality of cathode auxiliary wires disposed on the protective layer in a crisscross manner; wherein the cathode auxiliary wire and the cathode layer are electrically connected to reduce a voltage drop (IR drop) of the cathode layer.

2. The OLED display panel according to claim 1, wherein the cathode auxiliary wires correspond to a pattern of the black matrix, and are disposed on the protective layer in a crisscross manner.

3. The OLED display panel according to claim 1, wherein the cathode auxiliary wire is composed of any one of indium tin oxide, indium doped zinc oxide, silver magnesium, and an indium tin oxide/silver/indium tin oxide composite.

4. The OLED display panel according to claim 3, wherein the cathode auxiliary wire has a thickness of 300-5000 Å.

5. The OLED display panel according to claim 1, wherein the anode layer is composed of any one of indium tin oxide, indium doped zinc oxide, and an indium tin oxide/silver/indium tin oxide composite.

6. The OLED display panel according to claim 5, wherein the anode layer has a thickness of 100-3000 Å.

7. The OLED display panel according to claim 1, wherein the color filter layer has a thickness of 5000-50000 Å.

8. The OLED display panel according to claim 1, wherein the cathode layer is composed of any one of silver magnesium, indium doped zinc oxide, indium tin oxide, aluminum, indium tin oxide/silver/indium tin oxide composite, and indium doped zinc oxide/silver/indium doped zinc oxide composite.

9. The OLED display panel according to claim 8, wherein the cathode layer has a thickness of 100-3000 Å.

10. The OLED display panel according to claim 1, wherein the protective layer has a thickness of 5000-50000 Å.

11. An organic light emitting diode (OLED) display panel, comprising:
a first substrate;
a thin film transistor layer disposed on the first substrate;
a light emitting device layer disposed on the thin film transistor layer, comprising: an anode layer, a pixel defining layer, an organic light emitting layer, and a cathode layer;
a second substrate disposed opposite to the first substrate;
a color filter layer disposed on the second substrate, comprising a plurality of sub-pixels arranged in an array and a crisscrossed black matrix, wherein each of the sub-pixels is separated by the black matrix;
a protective layer disposed on the color filter layer;
a plurality of cathode auxiliary wires, the cathode auxiliary wire each is composed of any one of indium tin oxide, indium doped zinc oxide, silver magnesium, and an indium tin oxide/silver/indium tin oxide composite; wherein the cathode auxiliary wires correspond to a pattern of the black matrix, and are disposed on the protective layer in a crisscross manner; and wherein the cathode auxiliary wire and the cathode layer are electrically connected to reduce a voltage drop (IR drop) of the cathode layer.

12. The OLED display panel according to claim 11, wherein the cathode auxiliary wire has a thickness of 300-5000 Å.

13. The OLED display panel according to claim 11, wherein the anode layer is composed of any one of indium tin oxide, indium doped zinc oxide, and an indium tin oxide/silver/indium tin oxide composite.

14. The OLED display panel according to claim 13, wherein the anode layer has a thickness of 100-3000 Å.

15. The OLED display panel according to claim 11, wherein the color filter layer has a thickness of 5000-50000 Å.

16. The OLED display panel according to claim 11, wherein the cathode layer is composed of any one of silver magnesium, indium doped zinc oxide, indium tin oxide, aluminum, indium tin oxide/silver/indium tin oxide composite.

17. The OLED display panel according to claim 16, wherein the cathode layer has a thickness of 100-3000 Å.

18. The OLED display panel according to claim 11, wherein the protective layer has a thickness of 5000-50000 Å.
